(19) United States
(12) Patent Application Publication
(10) Pub. No.: US 2025/0294971 A1
(43) Pub. Date: Sep. 18, 2025

(54) LIGHT EMITTING APPARATUS, WEARABLE DEVICE, DISPLAY APPARATUS, PHOTOELECTRIC CONVERSION APPARATUS, AND ELECTRONIC EQUIPMENT

(71) Applicant: CANON KABUSHIKI KAISHA, Tokyo (JP)

(72) Inventors: KEI OKUMURA, Kanagawa (JP); MASATO YAJIMA, Tokyo (JP); TASUKU KANEDA, Kanagawa (JP); TOSHIYUKI OGAWA, Chiba (JP)

(21) Appl. No.: 19/065,481

(22) Filed: Feb. 27, 2025

(30) Foreign Application Priority Data
Mar. 12, 2024 (JP) 2024-038414

(51) Int. Cl. H10K 59/122; G09G 3/3233; H10K 59/80

(52) U.S. Cl. CPC H10K 59/122; G09G 3/3233; H10K 59/879; G09G 2300/0842; G09G 2320/045

(57) ABSTRACT

The present invention provides a light emitting apparatus comprising a plurality of pixels arranged in a substrate, wherein each of the plurality of pixels includes a first isolation portion configured in a trench-type to isolate two adjacent regions having different conductivity types from each other, and a second isolation portion configured in a trench-type to isolate two adjacent regions having the same conductivity type as each other, and a depth of the second isolation portion is larger than a depth of the first isolation portion.

### BACKGROUND OF THE INVENTION

### Field of the Invention

The present invention relates to a light emitting apparatus, a wearable device, a display apparatus, a photoelectric conversion apparatus, and electronic equipment.

### Description of the Related Art

An organic EL element is becoming the main light emitting apparatus (display apparatus) replacing liquid crystal due to its low power consumption and fast response speed, and further improvement in performance is being demanded. The organic EL element includes a pixel array in which an organic layer emits light. In the pixel array, a plurality of transistors for flowing currents corresponding to various luminance signal voltages are provided. It is known to use a Shallow Trench Isolation (STI) having a groove structure to electrically isolate the plurality of transistors. Japanese Patent Laid-Open No. 2020-71323 discloses that the STIs are formed at a constant depth within a pixel.

In the arrangement disclosed by Japanese Patent Laid-Open No. 2020-71323, to increase the pixel density along with a future high resolution, it can be demanded to reduce the isolation width between the transistors in the pixel array so as to reduce the pixel size. If the isolation width between the transistors is simply reduced to meet this demand, it will be difficult to maintain the breakdown voltage within the pixel, and deterioration of image quality (that is, degradation of display quality) such as degradation of display contrast due to a leakage current between the pixels may occur.

### SUMMARY OF THE INVENTION

The present invention provides, for example, a technique advantageous in achieving both maintaining the breakdown voltage in a pixel and reducing the pixel size in a light emitting apparatus.

According to one aspect of the present invention, there is provided a light emitting apparatus comprising a plurality of pixels arranged in a substrate, wherein each of the plurality of pixels includes a first isolation portion configured in a trench-type to isolate two adjacent regions having different conductivity types from each other, and a second isolation portion configured in a trench-type to isolate two adjacent regions having the same conductivity type as each other, and a depth of the second isolation portion is larger than a depth of the first isolation portion.

Further features of the present invention will become apparent from the following description of exemplary embodiments with reference to the attached drawings.

### BRIEF DESCRIPTION OF THE DRAWINGS

FIG. 1 is a block diagram showing an example of the arrangement of a light emitting apparatus according to the first embodiment;

FIG. 2 is an enlarged plan view of one pixel in the light emitting apparatus according to the first embodiment;

FIG. 3 is a sectional view of each pixel in the light emitting apparatus according to the first embodiment;

FIGS. 4A to 4D are views for explaining a method of forming the first element isolation portion and the second element isolation portion in a semiconductor substrate;

FIG. 5 is a sectional view of each pixel in a light emitting apparatus according to the second embodiment;

FIGS. 6A and 6B are sectional views showing an example of the arrangement of the pixel of the light emitting apparatus according to each embodiment;

FIG. 7 is a view showing an example of a display apparatus using the light emitting apparatus according to each embodiment;

FIG. 8 is a view showing an example of a photoelectric conversion apparatus using the light emitting apparatus according to each embodiment;

FIG. 9 is a view showing an example of electronic equipment using the light emitting apparatus according to each embodiment;

FIGS. 10A and 10B are views each showing an example of a display apparatus using the light emitting apparatus according to each embodiment; and

FIGS. 11A and 11B are views each showing an example of a wearable device using the light emitting apparatus according to each embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

Light emitting apparatuses according to the embodiments of the present invention will now be described. Note that all the following embodiments are mere examples of the present invention, and numerical values, shapes, materials, constituent elements, and arrangements and connection forms of the constituent elements are not intended to limit the scope of the present invention.

### First Embodiment

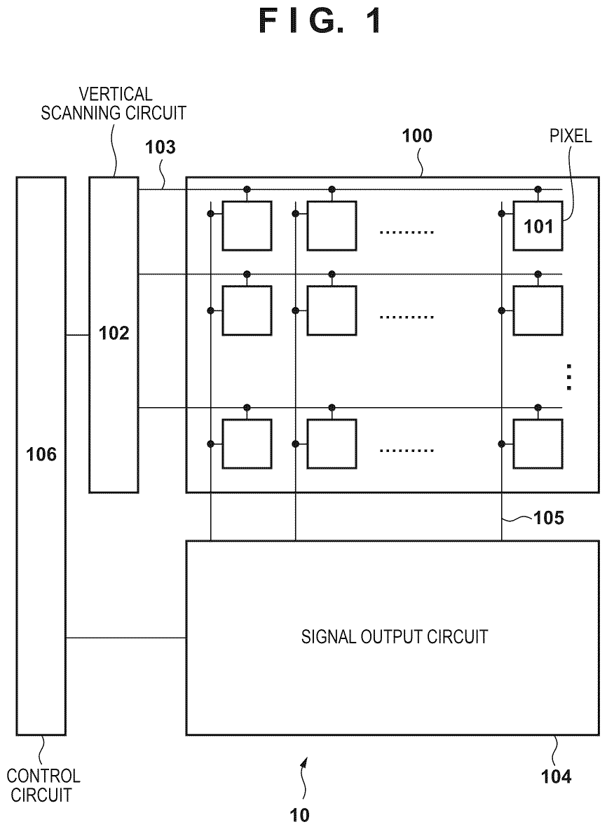

The first embodiment according to the present invention will be described. FIG. 1 is a block diagram showing an example of the arrangement of a light emitting apparatus 10 according to this embodiment. A pixel array 100 (pixel portion) includes a plurality of pixels 101 two-dimensionally (in a matrix) arrayed across a plurality of rows and a plurality of columns on a substrate. To each pixel 101, a control signal is input from a vertical scanning circuit 102 via a scanning line 103, and a luminance signal voltage is input from a signal output circuit 104 via a signal line 105. The vertical scanning circuit 102 and the signal output circuit 104 are controlled by a control circuit 106 (control unit). The signal output circuit 104 converts, into an analog signal voltage, image data input to pixels in each column scanned by the horizontal scanning circuit, and outputs a luminance signal voltage corresponding to the analog signal voltage to the signal line 105.

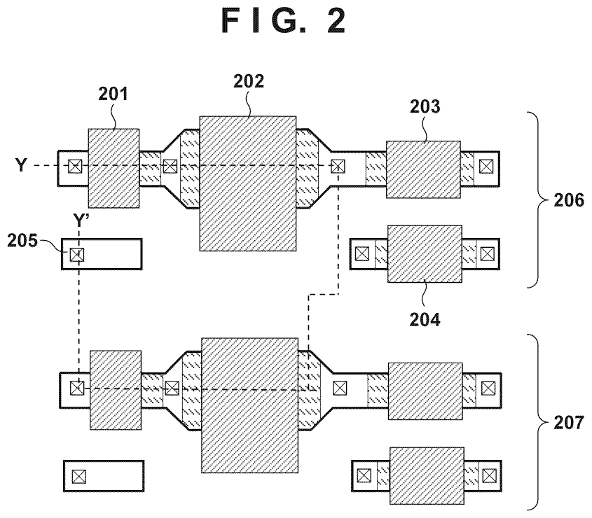

FIG. 2 is an enlarged plan view of one pixel 101 in the light emitting apparatus 10 according to this embodiment, and shows an example in which two sub-pixels (a first sub-pixel 206 and a second sub-pixel 207) having different light emission colors are arranged. Each sub-pixel can be formed from a switching transistor 201, a driving transistor 202, a reset transistor 203, a selection transistor 204, and a well contact 205 as one unit. The switching transistor 201 controls light emission of a light emitting element. The driving transistor 202 supplies, to the light emitting element, a current corresponding to data input as a luminance signal from the selection transistor 204, thereby driving the light emitting element. The reset transistor 203 resets the light emitting element. The selection transistor 204 controls input of data to the pixel (light emitting element). The well contact 205 electrically connects a well in a semiconductor substrate and a wiring layer arranged on the semiconductor substrate. In this embodiment, each of the switching transistor 201, the driving transistor 202, the reset transistor 203, and the selection transistor 204 includes a source/drain formed from a p-type semiconductor region, and the well contact 205 is formed from an n-type semiconductor region. The various kinds of transistors and the well contact are electrically isolated by trench-type (groove structure) element isolation portions to be described later. As the trench-type element isolation portion, a Shallow Trench Isolation (STI) can be used. Note that in this embodiment, a description will be given assuming that each of the various kinds of transistors has a p-type conductivity, but each transistor may have an n-type conductivity.

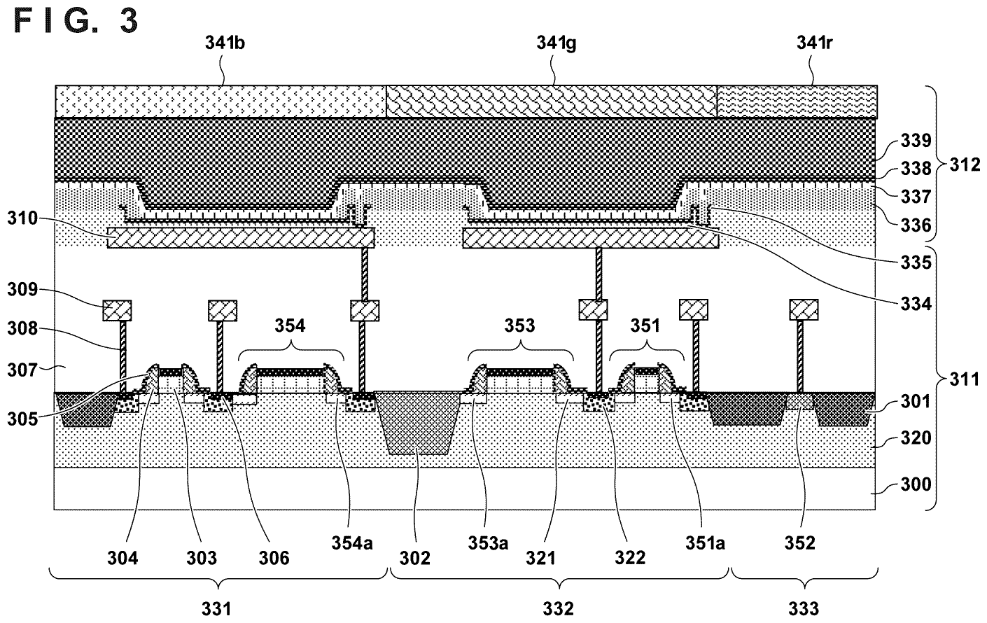

FIG. 3 shows an example of a sectional view of each pixel 101 in the light emitting apparatus 10 according to this embodiment. The sectional view of FIG. 3 is, for example, a sectional view taken along a line Y-Y′ in FIG. 2. Each pixel 101 in this embodiment can include a light emitting element 312 and a pixel circuit 311 that drives the light emitting element 312. Furthermore, in each pixel 101 in this embodiment, as trench-type element isolation portions that isolate the various kinds of transistors and the well contact in the pixel circuit 311, a first element isolation portion 301 and a second element isolation portion 302 are formed in a semiconductor substrate 300. The first element isolation portion 301 and the second element isolation portion 302 have different depths (trench depths). More specifically, the depth of the second element isolation portion 302 is larger than the depth of the first element isolation portion 301. Note that a description will be given below assuming that the pixel circuit 311 has a p-type conductivity, but it may have an n-type conductivity.

The pixel circuit 311 constituting the pixel array 100 (each pixel 101) is arranged in the semiconductor substrate 300, and the various kinds of transistors are formed in the pixel circuit 311. Each of the various kinds of transistors includes an n-type well 320, a p-type lightly doped region 321, a p-type source/drain 322, a gate electrode 303, a side wall 304, and a silicide prevention film 305. Two transistors adjacent to each other are isolated by the first element isolation portion 301 or the second element isolation portion 302. The first element isolation portion 301 and the second element isolation portion 302 may be properly used in one sub-pixel or between multiple sub-pixels, as shown in FIG. 3. In the latter case, for example, the first element isolation portion 301 alone may be used in one sub-pixel and the second element isolation portion 302 alone may be used in another sub-pixel. That is, various modifications and combinations of the first element isolation portion 301 and the second element isolation portion 302 are possible.

A silicide 306 is formed in a portion where the silicide prevention film 305 is not provided so that the semiconductor substrate 300 (for example, silicon) is exposed. A wiring interlayer film 307, a plug 308, a wiring 309, and a metal electrode 310 are formed on the silicide 306. The metal electrode 310 is divided into a B sub-pixel 331, a G sub-pixel 332, and an R sub-pixel 333. The light emitting element 312 that emits light of each color is formed on the metal layer 310 of each sub-pixel.

The light emitting element 312 includes an optical adjustment layer 334 having a height satisfying the optical interference condition of each light emission color, a transparent anode electrode 335, a pixel isolation layer 336, an organic light emitting layer 337, and a cathode electrode 338. A protection layer 339 is formed on the cathode electrode 338, and a blue color filter 341b, a green color filter 341g, and a red color filter 341r each having the spectral characteristics of the color of the corresponding sub-pixel are arranged on the protection layer 339. With this, light emission corresponding to the luminance signal voltage input to each sub-pixel can be obtained.

In the light emitting apparatus 10 according to this embodiment, the first element isolation portion 301 or the second element isolation portion 302 is arranged between the element regions (transistor region and well contact region) in the pixel circuit 311 in accordance with the required breakdown voltage. This can achieve both maintaining the breakdown voltage in the pixel 101 and reducing the pixel size. Note that as described above, the second element isolation portion 302 is formed to have a larger trench depth than that of the first element isolation portion 301.

The first element isolation portion 301 (first isolation portion) is arranged to electrically isolate two adjacent regions having different conductivity types. In this embodiment, the first element isolation portion 301 can be arranged between the well contact 205 and the adjacent switching transistor 201 and/or between the well contact 205 and the adjacent driving transistor 202. The first element isolation portion 301 may be arranged between the well contact 205 and the adjacent reset transistor 203 and/or between the well contact 205 and the adjacent selection transistor 204.

For example, in the example shown in FIG. 3, the conductivity type of a semiconductor region 351a (first semiconductor region) forming the source/drain of a transistor 351 is different from the conductivity type of a semiconductor region 352 (third semiconductor region) forming the adjacent well contact. Accordingly, the first element isolation portion 301 is arranged between the transistor 351 (semiconductor region 351a) and the well contact (semiconductor region 352).

On the other hand, the second element isolation portion 302 (second isolation portion) is arranged to electrically isolate two adjacent regions having the same conductivity type. In this embodiment, the second element isolation portion 302 can be arranged between two driving transistors 202 arranged adjacent to each other and/or between two reset transistors 203 arranged adjacent to each other. The second element isolation portion 302 can be arranged between two switching transistors arranged adjacent to each other. The second element isolation portion 302 may be arranged between the reset transistor and the adjacent switching transistor 201 and/or between the switching transistor 201 and the adjacent selection transistor 204.

For example, in the example shown in FIG. 3, a semiconductor region 353a (first semiconductor region) forming the source/drain of a transistor 353 and a semiconductor region 354a (second semiconductor region) forming the source/drain of an adjacent transistor 354 have the same conductivity type. Accordingly, the second element isolation portion 302 is arranged between the transistor 353 (semiconductor region 353a) and the transistor 354 (semiconductor region 354a).

The reason and effect of properly using the first element isolation portion 301 and the second element isolation portion 302 in the light emitting apparatus 10 according to this embodiment will be described below.

The source/drain region of each driving transistor is formed from a p-type semiconductor region. Therefore, between two driving transistors adjacent to each other, a PNP parasitic bipolar transistor constituted by the p-type source/drain 322, the n-type well 320, and the p-type source/drain 322 can be formed via the element isolation portion. To reduce a current flowing through the PNP parasitic bipolar transistor, it is effective to increase the base width of the parasitic bipolar transistor (that is, the width of the n-type region). However, increasing the width of the element isolation portion in a direction parallel to the surface of the semiconductor substrate 300 to increase the base width (the width of the n-type region) can make it difficult to reduce the pixel size. Therefore, in this embodiment, to increase the base width of the parasitic bipolar transistor (the width of the n-type region), the depth of the element isolation portion arranged between two driving transistors adjacent to each other is increased. That is, the second element isolation portion 302 is arranged between two driving transistors adjacent to each other. This can suppress the operation of the parasitic bipolar transistor while suppressing an increase in width of the element separation portion in the direction parallel to the surface of the semiconductor substrate 300.

The driving transistor is a transistor configured to flow a current corresponding to an arbitrary luminance signal voltage for each pixel. Accordingly, a higher voltage is applied to the source/drain region of the driving transistor than the other transistor such as the reset transistor, the switching transistor, or the selection transistor. Depending on the luminance signal in the pixel, the maximum voltage in the sub-pixel may be applied to the source/drain region of the driving transistor. Hence, the highest breakdown voltage in the pixel is required between the source/drain region of the driving transistor and the source/drain region of the adjacent driving transistor.

For the above reasons, in the light emitting apparatus 10 according to this embodiment, the second element isolation portion 302 is arranged between the driving transistor (for example, the transistor 353) and the adjacent driving transistor (for example, the transistor 354). From the same reasons, the second element isolation portion 302 can be arranged between two adjacent regions having the same conductivity type, such as between the reset transistor and the adjacent reset transistor.

On the other hand, the first element isolation portion 301 having the smaller depth than the second element isolation portion 302 can be arranged between the well contact and the adjacent reset transistor. Between the well contact and the adjacent reset transistor, a p-n junction constituted by the p-type source/drain 322, the n-type well 320, and the n-type source/drain is simply formed via the element isolation portion. As described above, there are two p-n junctions between the driving transistor and the adjacent driving transistor, it is necessary to suppress the operation of the parasitic bipolar transistor. On the other hand, only one p-n junction is formed in the vicinity of the well contact. Hence, the dependency of the breakdown voltage on the width of the n-type region is low. That is, it is possible to make the depth of the first element isolation portion 301 smaller (shallower) than the depth of the second element isolation portion 302. In general, the smaller the depth of the element isolation portion, the better the embedding characteristic of an insulating film. Thus, a finer isolation width can be achieved, that is advantageous in reducing the pixel size.

In addition, by arbitrarily controlling the potential of the well via the well contact portion, it is possible to reduce the leakage current flowing between the source and drain of the transistor by using the back gate effect on the transistor in the pixel circuit 311. In this case, by decreasing the depth of the element isolation portion around the well contact portion, the distance from the well contact region is shortened, and a potential drop can be reduced. Since the potential drop is reduced, variation of the back gate effect can be reduced.

In this manner, by properly using the first element isolation portion 301 and the second element isolation portion 302 in the light emitting apparatus 10 according to this embodiment, the above-described effects can be obtained. That is, in a location where the breakdown voltage is required, a leakage current in the pixel can be reduced by using the second element isolation portion 302, and in a location where there is a margin in breakdown voltage, the width of the element isolation portion can be decreased by using the first element isolation portion 301. Accordingly, it is possible to achieve both maintaining the breakdown voltage (suppressing degradation of display quality) in the pixel and reducing the pixel size in the light emitting apparatus 10.

### (Manufacturing Method of Light Emitting Apparatus)

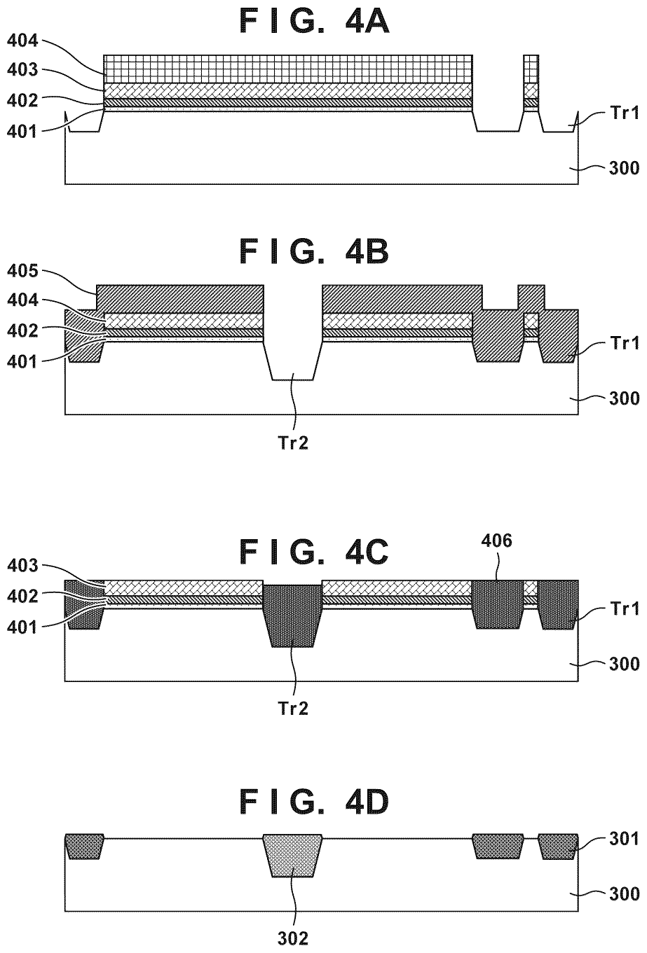

A manufacturing method of the light emitting apparatus 10 will be exemplarity described below with reference to the sectional view of FIG. 3 and sectional views of FIGS. 4A to 4D. First, with reference to FIGS. 4A to 4D, an example of a method of forming the first element isolation portion 301 and the second element isolation portion 302 in the semiconductor substrate 300 will be described.

FIG. 4A shows a step of forming a trench Tr1 constituting the first element isolation portion 301 in the semiconductor substrate 300. More specifically, a hard mask formed from an oxide film 401, polysilicon 402, and a silicon nitride film 403 is deposited on the semiconductor substrate 300, and a first photoresist 404 is applied on the hard mask. Then, the first photoresist 404 is patterned by photolithography to form an opening only in the region where the first element isolation portion 301 is to be formed. After the patterning, dry etching is performed using the first photoresist 404 as a mask, thereby forming the trench Tr1 in the semiconductor substrate 300.

FIG. 4B shows a step of forming a trench Tr2 constituting the second element isolation portion 302 in the semiconductor substrate 300. More specifically, after removing the first photoresist 404, a second photoresist 405 is applied on the semiconductor substrate 300. Then, the second photoresist 405 is patterned by photolithography to form an opening only in the region where the second element isolation portion 302 is to be formed. After the patterning, dry etching is performed using the second photoresist 405 as a mask, thereby forming the trench Tr2 in the semiconductor substrate 300.

Through the above-described steps, the depth of the trench (groove) of each of the first element isolation portion 301 and the second element isolation portion 302 can be arbitrarily changed. As an example, the depth of the trench is about 100 to 400 nm in the first element isolation portion 301, and is about 400 to 800 nm in the second element isolation portion 302. That is, the depth of the trench of the second element isolation portion 302 may be four to eight times larger than the depth of the trench of the first element isolation portion 301.

FIG. 4C shows a step of forming an insulator in each of the trenches Tr1 and Tr2 formed in the semiconductor substrate 300. More specifically, an insulating film is formed on the inner wall (side surface and bottom surface) of each of the trenches Tr1 and Tr2 using thermal oxidation in an oxidizing gas atmosphere or the like. After that, an insulator is filled into each of the trenches Tr1 and Tr2 so as to cover the insulating film formed on the inner wall of each of the trenches Tr1 and Tr2. The insulator to be filled into each of the trenches Tr1 and Tr2 is, for example, a silicon oxide film formed by a high density plasma CVD method. The insulator is deposited to a film thickness that allows it to fill each of the trenches Tr1 and Tr2 which are to be the first element isolation portion 301 and the second element isolation portion 302, respectively. The insulator filled in each trench Tr1 can be planarized by a combination of etching and Chemical Mechanical Polisher (CMP).

FIG. 4D shows a step of removing the hard mask on the semiconductor substrate 300. More specifically, the silicon nitride film 403 and the polysilicon 402 on the semiconductor substrate 300 are removed. Before removing the polysilicon 402, the film thickness of the insulator in each of the trenches Tr1 and Tr2 may be adjusted by wet etching. The oxide film 401 on the semiconductor substrate 300 may also be removed. With this step, the trench Tr1 is formed as the first element isolation portion 301, and the trench Tr2 is formed as the second element isolation portion 302. Here, since the first element isolation portion 301 and the second element isolation portion 302 have different trench depths, the height (protruding amount) from the surface of the semiconductor substrate 300 may be different between the first element isolation portion 301 and the second element isolation portion 302. Alternatively, wet etching may be used to control the heights (that is, the protruding amounts from the semiconductor substrate 300) of the first element isolation portion 301 and the second element isolation portion 302 to be the same.

Next, with reference to FIG. 3, an example of a method of manufacturing the pixel array 100 from the semiconductor substrate 300 formed with the first element isolation portion 301 and the second element isolation portion 302 will be described.

After the first element isolation portion 301 and the second element isolation portion 302 are formed in the semiconductor substrate 300 through the above-described step shown in FIG. 4D, a thermal oxide film is formed on the surface of the semiconductor substrate 300. The thermal oxide film is provided for the purpose of suppressing channeling during ion implantation and the like. In a state where a predetermined region is protected by a resist, the n-type well 320 is formed by multi-stage ion implantation. The multi-stage ion implantation can be adjusted, for example, in the range of the acceleration energy of 10 to 2,000 keV and the dose amount of about 1×10¹¹ to 5×10¹³/cm². The dose amount may be changed depending on the depth of the multi-stage ion implantation. The n-type well 320 may be formed to have a high concentration in the region shallower than the bottom portions of the first element isolation portion 301 and the second element isolation portion 302 and have a low concentration in the region deeper than the bottom portions of the first element isolation portion 301 and the second element isolation portion 302.

Then, the gate oxide film and the gate electrode 303 are formed.

Thereafter, in a state where a predetermined region is protected by a resist, the p-type lightly doped region 321 is formed by ion implantation. The ion implantation can be adjusted, for example, in the range of the acceleration energy of 10 to 150 keV and the dose amount of about 1×10¹¹ to 5×10¹⁴/cm². The dose amount may be changed depending on the depth of the multi-stage ion implantation.

Then, the side wall 304 of the transistor is formed. The side wall 304 can be formed by depositing a silicon oxide film and a silicon nitride film and then etching them back. The side wall 304 may be a single layer of the silicon oxide film or the silicon nitride film, or may have a stacked structure thereof.

Then, in a state where a predetermined region is protected by a resist, the p-type source/drain 322 is formed by ion implantation. At this time, to form an offset MOSFET, a resist pattern may be formed such that the p-type source/drain 322 is implanted at a predetermined distance from the end portion of the gate electrode 303. The ion implantation can be adjusted, for example, in the range of the acceleration energy of 3 to 30 keV and the dose amount of about 1e¹³ to 7e¹⁵/cm². Then, annealing for dopant activation can be sequentially performed.

Here, the second element isolation portion 302 is desirably formed to have the depth larger than the depth of the first element isolation portion 301 by 0.3 μm or more. Note that the second element isolation portion 302 is desirably formed to have the depth shallower than the bottom portion of the n-type well 320. This is because if the depth of the second element isolation portion 302 is deeper than the bottom portion of the well 320, the potential of the well 320 becomes floating and a leakage current may be generated.

It is also desirable that the first element isolation portion 301 (trench Tr1) is formed to have a narrower opening width in the direction parallel to the surface of the semiconductor substrate 300 than that of the second element isolation portion 302 (trench Tr2). This is to shorten the distance between the well contact and the transistor and reduce a potential drop. The minimum opening width of the first element isolation portion 301 is preferably 0.1 μm or more and less than 0.2 μm, and the minimum opening width of the second element isolation portion 302 is preferably 0.2 μm or more and less than 0.5 μm. The depth and opening width of each element isolation portion may be appropriately changed in accordance with the voltage required for each pixel. By using the first element isolation portion 301 in a location where a source-drain breakdown voltage is unnecessary, the opening width can be reduced, and this can contribute to a reduction in pixel pitch.

Note that in this embodiment, an example has been described in which two kinds of element isolation portions (the first element isolation portion 301 and the second element isolation portion 302) are provided in each pixel 101, but the present invention is not limited to this. Three or more kinds of element isolation portions different in the depth or opening width may be provided in each pixel 101.

Then, to define the region of the metal silicide, a silicide protection by an oxide film is formed. The silicide protection is formed to prevent formation of the metal silicide in the Lightly Doped Drain (LDD) region. After that, contact plugs are formed, and a multi-layer wiring layer is formed.

The optical adjustment layers 334 having different heights are formed on the metal electrodes 310 in accordance with the interference of the light emission wavelengths of the B sub-pixel 331, the G sub-pixel 332, and the R sub-pixel 333. On the optical adjustment layer 334, the transparent anode electrode 335, the pixel isolation layer 336 for isolating pixels, the organic light emitting layer 337, and the cathode electrode 338 are deposited in the order. After the protection layer 339 is further deposited on the cathode electrode 338, the blue color filter 341b, the green color filter 341g, and the red color filter 341r are formed on the protection layer 339.

As described above, in each pixel 101 in the light emitting apparatus 10 according to this embodiment, the first trench-type element isolation portion 301 and the second trench-type element isolation portion 302 having a larger depth than the first element isolation portion 301 are arranged. The first element isolation portion 301 is arranged to electrically isolate two adjacent regions having different conductivity types, and the second element isolation portion 302 is arranged to electrically isolate two adjacent regions having the same conductivity type. This can achieve both maintaining the breakdown voltage in the pixel 101 and reducing the pixel size. Here, the light emitting apparatus 10 according to this embodiment need not always be formed in accordance with the above-described manufacturing method and step order, and replacement, change, and the like of various steps are possible. The trench depths and the order of steps may be reversed. This embodiment has been made to exemplify several modes to which the present invention can be applied. Various changes and modification can appropriately be made without departing from the spirit and scope of the present invention.

### Second Embodiment

The second embodiment according to the present invention will be described. This embodiment basically takes over the first embodiment, and matters not mentioned below can follow the first embodiment.

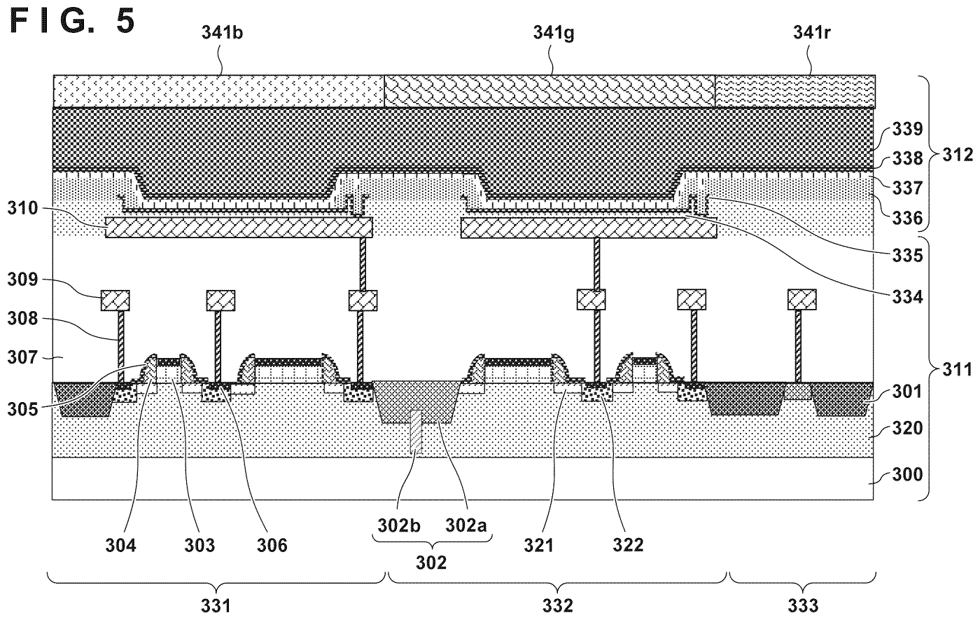

FIG. 5 shows an example of a sectional view of each pixel 101 in a light emitting apparatus 10 according to this embodiment. In this embodiment, an example will be described in which a second element isolation portion 302 is formed to include an upper layer portion 302a and a lower layer portion 302b stacked on each other. Note that an example will be described in which the second element isolation portion 302 in this embodiment has a two-stage structure combining the upper layer portion 302a and the lower layer portion 302b, but the present invention is not limited to this, and a structure of three or more stages combining three or more layer portions may be used.

The second element isolation portion 302 in this embodiment is formed by connecting the lower layer portion 302b to a part of the bottom surface of the upper layer portion 302a. The width (diameter or area) of the part of the bottom surface of the upper layer portion 302a to which the lower layer portion 302b is connected is preferably smaller than the width (diameter or area) of the bottom surface of the upper layer portion 302a. “The portion of the bottom surface of the upper layer portion 302a to which the lower layer portion 302b is connected” may be understood to be the upper portion (connected portion) of the lower layer portion 302b connected to the upper layer portion 302a. The maximum width (diameter or area) of the lower layer portion 302b is preferably smaller than the width (diameter or area) of the bottom surface of the upper layer portion 302a.

In the second element isolation portion 302 in this embodiment, the depth of the lower layer portion 302b is preferably larger than the depth of the upper layer portion 302a. That is, the ratio of the depth of the lower layer portion 302b to the depth of the upper layer portion 302a is preferably 1 or more. Further, in the second element isolation portion 302 in this embodiment, the opening width of the trench constituting the upper layer portion 302a is preferably larger than the opening width of the trench constituting the lower layer portion 302b. With this, it is possible to arbitrarily control the width of the active region of a transistor in a semiconductor region by the opening width of the upper layer portion 302a of the second element isolation portion 302.

As described above, in this embodiment, the second element isolation portion 302 is formed from the upper layer portion 302a and the lower layer portion 302b. This allows formation of the upper layer portion 302a of the second element isolation portion 302 and a first element isolation portion 301 in the same step. Accordingly, an effect of making the height from the surface of a semiconductor substrate 300 constant (the same) between the first element isolation portion 301 and the second element isolation portion 302 can be obtained. When the height from the surface of the semiconductor substrate 300 is constant between the element isolation portions 301 and 302, the flatness of the semiconductor substrate 300 during processing is improved, so that the gate electrode and the like can be processed more finely. In addition, according to this embodiment, the depth of the upper layer portion 302a of the second element isolation portion 302 can be made smaller (shallower) than the depth of the entire second element isolation portion 302 in the first embodiment. Accordingly, an insulator is more advantageously (easily) embedded into a trench Tr2, and the trench width itself can also be formed more finely.

### [Configuration of Organic Light Emitting Element]

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer can be provided between the protection layer and the color filter. The planarizing layer can be made of acrylic resin or the like. The same applies to a case in which a planarizing layer is provided between the color filter and the microlens.

### [Substrate]

Quartz, glass, a silicon wafer, a resin, a metal, or the like may be used as a substrate. Furthermore, a switching element such as a transistor and a wiring may be provided on the substrate, and an insulating layer may be provided thereon. The insulating layer may be made of any material as long as a contact hole can be formed so that the wiring can be formed between the insulating layer and the first electrode and insulation from the unconnected wiring can be ensured. For example, a resin such as polyimide, silicon oxide, silicon nitride, or the like can be used.

[Electrode]A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a work function as large as possible is preferably used. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used.

One of these electrode materials may be used singly, or two or more of them may be used in combination. The anode may be formed by a single layer or a plurality of layers.

If the anode is used as a reflective electrode, for example, chromium, aluminum, silver, titanium, tungsten, molybdenum, an alloy thereof, a stacked layer thereof, or the like can be used. The above materials can function as a reflective film having no role as an electrode. If the anode is used as a transparent electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function is preferably used. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Among others, silver is preferably used. To suppress aggregation of silver, a silver alloy is more preferably used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but direct current sputtering or alternating current sputtering is preferably used since the good film coverage is provided and the resistance is easily lowered.

### [Pixel Isolation Layer]

A pixel isolation layer is formed by a silicon nitride (SiN) film, a silicon oxynitride (SiON) film, or a silicon oxide (SiO) film formed using a Chemical Vapor Deposition method (CVD method). To increase the resistance in the in-plane direction of the organic compound layer, the organic compound layer, especially the hole transport layer is preferably thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, it is preferable to adjust the taper angle of the side wall of the pixel isolation layer or the film thickness of the pixel isolation layer to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer is desirably 10 nm (inclusive) to 150 nm (inclusive). A similar effect can be obtained in a configuration including only pixel electrodes without the pixel isolation layer. However, in this case, the film thickness of the pixel electrode is preferably set to be equal to or smaller than half the film thickness of the organic layer or the end portion of the pixel electrode is preferably formed to have a forward tapered shape of less than 600 because short circuit of the organic light emitting element can be reduced.

### [Organic Compound Layer]

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer can be arranged between the first and second electrodes, and may be arranged in contact with the first and second electrodes.

If a plurality of light emitting layers are provided, a charge generation portion may be arranged between the first light emitting layer and the second light emitting layer. The charge generation portion may contain an organic compound with a lowest unoccupied molecular orbital energy (LUMO) of −5.0 eV or less. The same applies to a case where a charge generation portion is provided between the second light emitting layer and the third light emitting layer.

### [Protection Layer]

A protection layer may be provided on the second electrode. For example, by adhering glass provided with a moisture absorbing agent on the second electrode, permeation of water or the like into the organic compound layer can be suppressed and occurrence of display defects can be suppressed. Furthermore, as another embodiment, a passivation film made of silicon nitride or the like may be provided on the cathode to suppress permeation of water or the like into the organic compound layer. For example, the protection layer can be formed by forming the cathode, transferring it to another chamber without breaking the vacuum, and forming a silicon nitride film having a thickness of 2 m by a CVD method. The protection layer may be provided using an atomic deposition method (ALD method) after deposition using the CVD method. The material of the film by the ALD method is not limited but can be silicon nitride, silicon oxide, aluminum oxide, or the like. A silicon nitride film may further be formed by the CVD method on the film formed by the ALD method. The film formed by the ALD method may have a film thickness smaller than that of the film formed by the CVD method. More specifically, the film thickness of the film formed by the ALD method may be 50% or less, or 10% or less.

### [Color Filter]

A color filter may be provided on the protection layer. For example, a color filter considering the size of the organic light emitting element may be provided on another substrate, and this substrate may be bonded to the substrate with the organic light emitting element provided thereon. Alternatively, a color filter may be patterned on the above-described protection layer using a photolithography technique. The color filter can be formed from a polymeric material.

### [Planarizing Layer]

A planarizing layer may be provided between the color filter and the protection layer. The planarizing layer is provided to reduce unevenness of the lower layer. The planarizing layer may be called a material resin layer without limiting the purpose of the layer. The planarizing layer can be formed from an organic compound, and can be made of a low-molecular material or a polymeric material. However, a polymetric material is more preferable.

The planarizing layers may be provided above and below the color filter, and the same or different materials may be used for them. More specifically, examples of the material include polyvinyl carbazole resin, polycarbonate resin, polyester resin, ABS resin, acrylic resin, polyimide resin, phenol resin, epoxy resin, silicone resin, and urea resin.

### [Microlens]

The organic light emitting apparatus can include an optical member such as a microlens on the light emission side. The microlens can be made of acrylic resin, epoxy resin, or the like. The microlens can aim to increase the amount of light extracted from the organic light emitting apparatus and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface is preferably arranged on the functional layer side of the first surface. For this configuration, the microlens needs to be formed on the light emitting apparatus. If the functional layer is an organic layer, it is preferable to avoid a process which produces high temperature in the manufacturing step. In addition, if it is configured to arrange the second surface on the functional layer side of the first surface, all the glass transition temperatures of an organic compound forming the organic layer are preferably 100° C. or more, and more preferably 130° C. or more.

### [Counter Substrate]

A counter substrate can be provided on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### [Organic Layer]

The organic compound layer (hole injection layer, hole transport layer, electron blocking layer, light emitting layer, hole blocking layer, electron transport layer, electron injection layer, and the like) forming the organic light emitting element according to an embodiment of the present invention is formed by the method to be described below.

The organic compound layer forming the organic light emitting element according to the embodiment of the present invention can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### [Pixel Circuit]

The light emitting apparatus can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting apparatus includes a display region and a peripheral region arranged around the display region. The light emitting apparatus includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### [Pixel]

The organic light emitting apparatus includes a plurality of pixels. Each pixel includes sub-pixels that emit light components of different colors. The sub-pixels include, for example, R, G, and B emission colors, respectively.

In each pixel, a region also called a pixel opening emits light. This region is the same as the first region. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. Here, these shapes need not be correct shapes, and a shape close to a rectangle is included in a rectangle. The shape of the sub-pixel and the pixel arrangement can be used in combination.

### [Application of Organic Light Emitting Element of Embodiment of Present Invention]

The organic light emitting element according to an embodiment of the present invention can be used as a constituent member of a display apparatus or an illumination apparatus. In addition, the organic light emitting element is applicable to the exposure light source of an electrophotographic image forming apparatus, the backlight of a liquid crystal display apparatus, a light emitting apparatus including a color filter in a white light source, and the like.

The display apparatus may be an image information processing apparatus that includes an image input unit for inputting image information from an area CCD, a linear CCD, a memory card, or the like, and an information processing unit for processing the input information, and displays the input image on a display unit.

In addition, a display unit included in an image capturing apparatus or an inkjet printer can have a touch panel function. The driving type of the touch panel function may be an infrared type, a capacitance type, a resistive film type, or an electromagnetic induction type, and is not particularly limited. The display apparatus may be used for the display unit of a multifunction printer.

A display apparatus according to this embodiment will be described with reference to drawings.

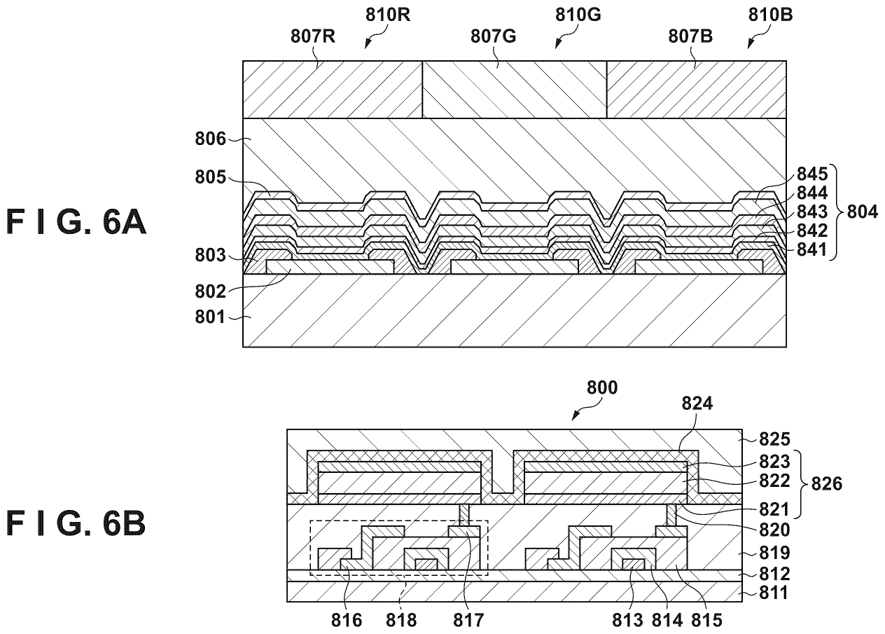

FIGS. 6A and 6B are schematic sectional views showing an example of a display apparatus including an organic light emitting element and a transistor connected to the organic light emitting element. The transistor is an example of an active element. The transistor may be a thin-film transistor (TFT).

FIG. 6A shows an example of a pixel that is a constituent element of the display apparatus according to this embodiment. The pixel includes sub-pixels 810 (pixels PIX). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 may include a transistor and a capacitive element arranged in the interlayer insulating layer 801 or a layer below it. The transistor and the first electrode can electrically be connected via a contact hole (not shown) or the like.

The insulating layer 803 is also called a bank or a pixel isolation film. The insulating layer 803 covers the end of the first electrode, and is arranged to surround the first electrode. A portion where no insulating layer is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode 805 may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

The display apparatus 800 (corresponding to the light emitting apparatus 10 according to the above-described embodiment) shown in FIG. 6B is provided with an organic light emitting element 826 and a TFT 818 as an example of a transistor. A substrate 811 of glass, silicon, or the like is provided and an insulating layer 812 is provided on the substrate 811. An active element 818 such as a TFT is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

Note that a method of electrically connecting the electrodes (anode and cathode) included in the organic light emitting element 826 and the electrodes (source electrode and drain electrode) included in the TFT is not limited to that shown in FIG. 6B. That is, one of the anode and cathode and one of the source electrode and drain electrode of the TFT are electrically connected. The TFT indicates a thin-film transistor.

In the display apparatus 800 shown in FIG. 6B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display apparatus 800 shown in FIG. 6B, but another switching element may be used instead.

The transistor used in the display apparatus 800 shown in FIG. 6B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display apparatus 800 shown in FIG. 6B may be formed in the substrate such as an Si substrate. Forming the transistor in the substrate means forming the transistor by processing the substrate such as an Si substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Note that the switching element according to this embodiment is not limited to the TFT, and may be a transistor formed from low-temperature polysilicon or an active matrix driver formed on the substrate such as an Si substrate. The term “on the substrate” may mean “in the substrate”. Whether to provide a transistor in the substrate or use a TFT is selected based on the size of the display unit. For example, if the size is about 0.5 inch, the organic light emitting element is preferably provided on the Si substrate.

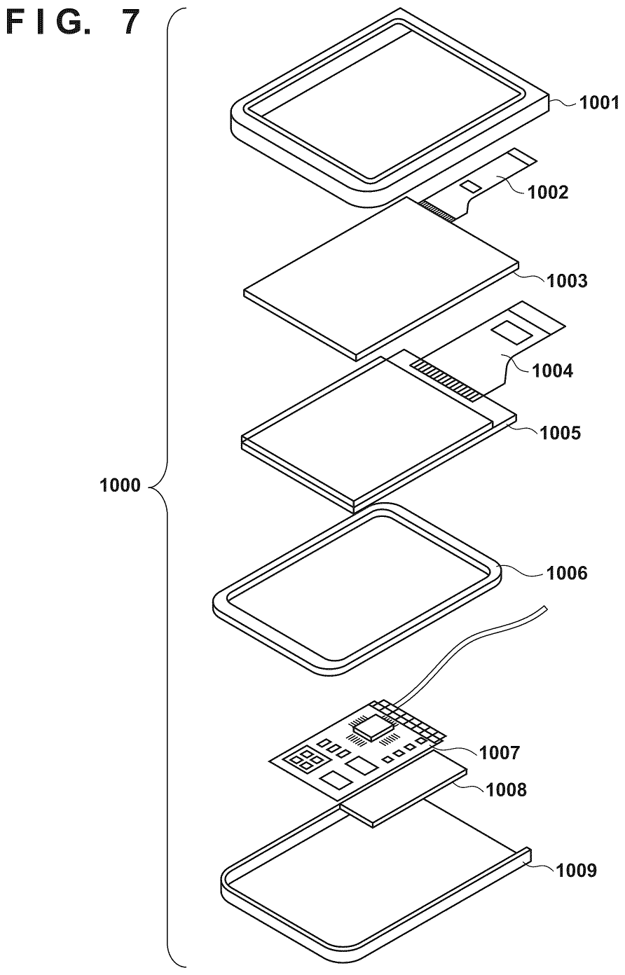

FIG. 7 is a schematic view showing an example of the display apparatus according to this embodiment. A display apparatus 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Transistors are printed on the circuit board 1007. The battery 1008 is unnecessary if the display apparatus is not portable equipment. Even when the display apparatus is a portable equipment, the battery 1008 may be provided at another position.

The display apparatus according to this embodiment can include color filters of red, green, and blue. The color filters of red, green, and blue can be arranged in a delta array.

The display apparatus according to this embodiment may be used as a display unit of a portable terminal. At this time, the display unit can have both a display function and an operation function. Examples of the portable terminal are a portable phone such as a smartphone, a tablet, and a head mounted display.

The display apparatus according to this embodiment can be used for a display unit of an image capturing apparatus including an optical unit having a plurality of lenses, and an image sensor for receiving light having passed through the optical unit. The image capturing apparatus can include a display unit for displaying information acquired by the image sensor. In addition, the display unit can be either a display unit exposed outside the image capturing apparatus, or a display unit arranged in the finder. The image capturing apparatus can be a digital camera or a digital video camera.

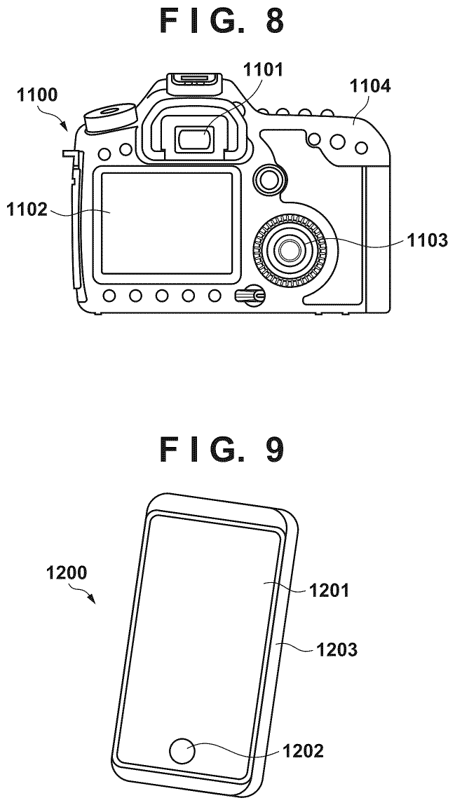

FIG. 8 is a schematic view showing an example of the image capturing apparatus according to this embodiment. An image capturing apparatus 1100 can include a viewfinder 1101, a rear display 1102, an operation unit 1103, and a housing 1104. The viewfinder 1101 may include the display apparatus according to this embodiment. In this case, the display apparatus can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. It is therefore preferable to use the display apparatus using the organic light emitting element according to the present invention. This is so because the organic light emitting element has a high response speed. The display apparatus using the organic light emitting element can be used for the apparatuses that require a high display speed more preferably than for the liquid crystal display apparatus.

The image capturing apparatus 1100 includes an optical unit (not shown). This optical unit has a plurality of lenses, and forms an image on an image capturing element accommodated in the housing 1104. The focal points of the plurality of lenses can be adjusted by adjusting the relative positions. This operation can also automatically be performed. The image capturing apparatus may be called a photoelectric conversion apparatus. The photoelectric conversion apparatus can include, as an image capturing method, not a method of sequentially capturing images but a method of detecting the difference from a preceding image, a method of extracting an image from an always recorded image, and the like.

FIG. 9 is a schematic view showing an example of electronic equipment according to this embodiment. Electronic equipment 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit can also be a biometric authentication unit that performs unlocking or the like by authenticating the fingerprint. The electronic equipment including the communication unit can also be regarded as communication equipment. The electronic equipment may also have a camera function by including a lens and an image sensor. An image captured by the camera function is displayed on the display unit. Examples of the electronic equipment are a smartphone and a laptop computer.

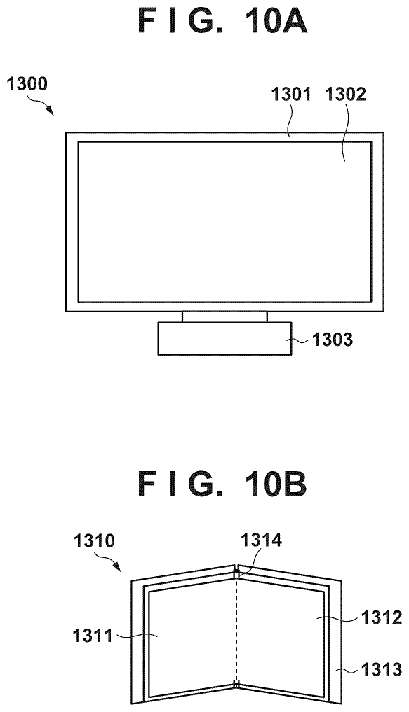

FIGS. 10A and 10B are schematic views showing examples of the display apparatus according to this embodiment. FIG. 10A shows a display apparatus such as a television monitor or a PC monitor. A display apparatus 1300 includes a frame 1301 and a display unit 1302. The light emitting apparatus according to this embodiment can be used for the display unit 1302.

The display apparatus 1300 includes a base 1303 that supports the frame 1301 and the display unit 1302. The base 1303 is not limited to the form shown in FIG. 10A. The lower side of the frame 1301 may also function as the base.

In addition, the frame 1301 and the display unit 1302 can be bent. The radius of curvature in this case can be 5,000 mm (inclusive) to 6,000 mm (inclusive).

FIG. 10B is a schematic view showing another example of the display apparatus according to this embodiment. A display apparatus 1310 shown in FIG. 10B can be folded, and is a so-called foldable display apparatus. The display apparatus 1310 includes a first display unit 1311, a second display unit 1312, a housing 1313, and a bending point 1314. Each of the first display unit 1311 and the second display unit 1312 may include the light emitting apparatus according to this embodiment. The first display unit 1311 and the second display unit 1312 can also be one seamless display apparatus. The first display unit 1311 and the second display unit 1312 can be divided by the bending point. The first display unit 1311 and the second display unit 1312 can display different images, and the first and second display units can also display one image together.

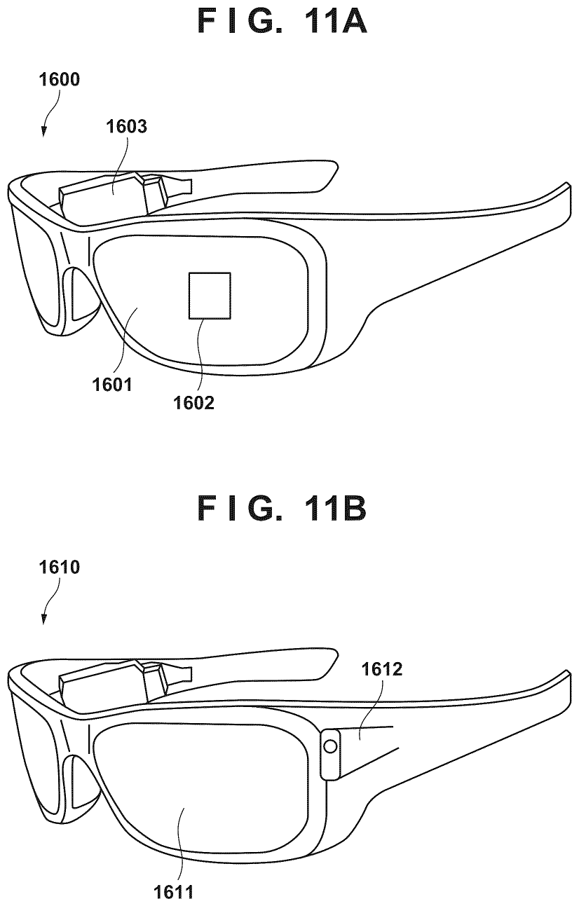

Application examples of the display apparatus according to each embodiment described above will be described with reference to FIGS. 11A and 11B. The display apparatus can be applied to a system that can be worn as a wearable device such as smartglasses, an HMD, or a smart contact lens. An image capturing display apparatus used for such application examples includes an image capturing apparatus capable of photoelectrically converting visible light and a display apparatus capable of emitting visible light.

Glasses 1600 (smartglasses) according to one application example will be described with reference to FIG. 11A. An image capturing apparatus 1602 such as a CMOS sensor or an SPAD is provided on the surface side of a lens 1601 of the glasses 1600. In addition, the display apparatus according to each embodiment described above is provided on the back surface side of the lens 1601.

The glasses 1600 further include a control apparatus 1603. The control apparatus 1603 functions as a power supply that supplies electric power to the image capturing apparatus 1602 and the display apparatus according to each embodiment. In addition, the control apparatus 1603 controls the operations of the image capturing apparatus 1602 and the display apparatus. An optical system configured to condense light to the image capturing apparatus 1602 is formed on the lens 1601.

Glasses 1610 (smartglasses) according to one application example will be described with reference to FIG. 11B. The glasses 1610 include a control apparatus 1612. An image capturing apparatus corresponding to the image capturing apparatus 1602 and the display apparatus are mounted on the control apparatus 1612. An optical system configured to project light emitted from the display apparatus in the control apparatus 1612 is formed in a lens 1611, and an image is projected to the lens 1611. The control apparatus 1612 functions as a power supply that supplies electric power to the image capturing apparatus and the display apparatus, and controls the operations of the image capturing apparatus and the display apparatus. The control apparatus may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display apparatus according to an embodiment of the present invention can include an image capturing apparatus including a light receiving element, and control an image displayed on the display apparatus based on the line-of-sight information of the user from the image capturing apparatus.

More specifically, the display apparatus decides a first display region at which the user is gazing and a second display region other than the first display region based on the line-of-sight information. The first display region and the second display region may be decided by the control apparatus of the display apparatus, or those decided by an external control apparatus may be received. In the display region of the display apparatus, the display resolution of the first display region may be controlled to be higher than the display resolution of the second display region. That is, the resolution of the second display region may be lower than that of the first display region.

In addition, the display region includes a first display region and a second display region different from the first display region, and a region of higher priority is decided from the first display region and the second display region based on line-of-sight information. The first display region and the second display region may be decided by the control apparatus of the display apparatus, or those decided by an external control apparatus may be received. The resolution of the region of higher priority may be controlled to be higher than the resolution of the region other than the region of higher priority. That is, the resolution of the region of relatively low priority may be low.

Note that AI may be used to decide the first display region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display apparatus, the image capturing apparatus, or an external apparatus. If the external apparatus holds the AI program, it is transmitted to the display apparatus via communication.

When performing display control based on line-of-sight detection, it can suitably be applied to smartglasses further including an image capturing apparatus configured to capture the outside. The smartglasses can display captured outside information in real time.

As described above, when an apparatus using the organic light emitting element according to this embodiment is used, it is possible to perform stable display with high quality even in long time display.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-038414 filed on Mar. 12, 2024, which is hereby incorporated by reference herein in its entirety.

What is claimed is:

1. A light emitting apparatus comprising a plurality of pixels arranged in a substrate, wherein
each of the plurality of pixels includes a first isolation portion configured in a trench-type to isolate two adjacent regions having different conductivity types from each other, and a second isolation portion configured in a trench-type to isolate two adjacent regions having the same conductivity type as each other, and
a depth of the second isolation portion is larger than a depth of the first isolation portion.

2. The apparatus according to claim 1, wherein the depth of the second isolation portion is larger than the depth of the first isolation portion by not less than 0.3 μm.

3. The apparatus according to claim 1, wherein in a direction parallel to a surface of the substrate, an opening width of the first isolation portion is narrower than an opening width of the second isolation portion.

4. The apparatus according to claim 1, wherein a height from a surface of the substrate is different between the first isolation portion and the second isolation portion.

5. The apparatus according to claim 1, wherein
the second isolation portion includes an upper layer portion and a lower layer portion stacked on each other, and
the lower layer portion is connected to a part of a bottom surface of the upper layer portion.

6. The apparatus according to claim 5, wherein a depth of the lower layer portion is larger than a depth of the upper layer portion.

7. The apparatus according to claim 5, wherein a maximum width of the lower layer portion is smaller than a width of the bottom surface of the upper layer portion.

8. The apparatus according to claim 1, wherein
each of the plurality of pixels includes a first semiconductor region, a second semiconductor region having the same conductivity type as the first semiconductor region, and a third semiconductor region having a conductivity type different from a conductivity type of the first semiconductor region, and
the first isolation portion is provided between the first semiconductor region and the third semiconductor region arranged adjacent to each other, and the second isolation portion is provided between the first semiconductor region and the second semiconductor region arranged adjacent to each other.

9. The apparatus according to claim 8, wherein
each of the plurality of pixels includes a light emitting element and a pixel circuit configured to drive the light emitting element, and
the pixel circuit includes a selection transistor configured to control input of data to a pixel, and a driving transistor configured to drive the light emitting element in accordance with input data.

10. The apparatus according to claim 9, wherein the second isolation portion is provided between the two driving transistors arranged adjacent to each other.

11. The apparatus according to claim 9, wherein the pixel circuit further includes a switching transistor configured to control light emission of the light emitting element, and a reset transistor configured to reset the light emitting element.

12. The apparatus according to claim 11, wherein the second isolation portion is provided between the two reset transistors arranged adjacent to each other.

13. The apparatus according to claim 11, wherein the second isolation portion is provided between the reset transistor and the switching transistor adjacent to the reset transistor.

14. The apparatus according to claim 11, wherein the second isolation portion is provided between the switching transistor and the selection transistor adjacent to the switching transistor.

15. The apparatus according to claim 11, wherein the first isolation portion is provided between a well contact of a pixel and the reset transistor adjacent to the well contact.

16. The apparatus according to claim 9, wherein the first isolation portion is provided between a well contact of a pixel and the selection transistor adjacent to the well contact.

17. The apparatus according to claim 9, wherein the first isolation portion is provided between a well contact of a pixel and the driving transistor adjacent to the well contact.

18. A wearable device comprising a display apparatus configured to display an image,
wherein the display apparatus includes a light emitting apparatus defined in claim 1.

19. A display apparatus comprising a light emitting apparatus defined in claim 1, and an active element connected to the light emitting apparatus.

20. A photoelectric conversion apparatus comprising an optical unit including a plurality of lenses, an image sensor configured to receive light having passed through the optical unit, and a display unit configured to display an image,
wherein the display unit displays an image captured by the image sensor, and includes a light emitting apparatus defined in claim 1.

21. Electronic equipment comprising a housing provided with a display unit, and a communication unit provided in the housing and configured to perform external communication,
wherein the display unit includes a light emitting apparatus defined in claim 1.
